(19) United States
(12) Patent Application Publication
(10) Pub. No.: US 2009/0084866 A1
(43) Pub. Date: Apr. 2, 2009

(54) Vibration balanced synthetic jet ejector

(75) Inventors: Daniel N. Grimm, Round Rock, TX (US); Ronald Lutz, Round Rock, TX (US); Raghavendran Mahalingam, Austin, TX (US); John Stanley Booth, Austin, TX (US); Markus Schwickert, Austin, TX (US)

Correspondence Address: FORTKORT & HOUSTON P.C., 9442 N. CAPITAL OF TEXAS HIGHWAY, ARBORETUM PLAZA ONE, SUITE 500, AUSTIN, TX, 78759, US

(73) Assignee: Nuventix Inc.

(21) Appl. No.: 12/286,794

(22) Filed: Oct. 1, 2008

Related U.S. Application Data
(60) Provisional application No. 60/997,256, filed on Oct. 1, 2007.

(51) Int. Cl. B05B 17/04; H01L 41/08; F15C 3/16

(52) U.S. Cl. 239/4; 165/104.33; 239/102.2; 310/326

(57) ABSTRACT

A synthetic jet ejector is provided which comprises (a) an LED (119), (b) a heat sink (121), (c) a first synthetic jet actuator (111) equipped with a first diaphragm (162) which is adapted to vibrate such that it undergoes displacements along a first axis, and (d) a second synthetic jet actuator (113) equipped with a second diaphragm (163) which is adapted to vibrate such that it undergoes displacements in an opposite direction along said first axis from said first diaphragm.

### CROSS REFERENCE TO RELATED APPLICATION

This application claims the benefit of priority from U.S. Provisional Application No. 60/997,256, filed Oct. 1, 2007, having the same title, and having the same inventors, and which is incorporated herein by reference in its entirety.

### FIELD OF THE DISCLOSURE

The present disclosure relates generally to thermal management devices, and more particularly to thermal management devices with reduced vibration.

### BACKGROUND OF THE DISCLOSURE

A variety of thermal management devices are known to the art, including conventional fan based systems, piezoelectric systems, and synthetic jet ejectors. The latter type of system has emerged as a highly efficient and versatile solution where thermal management is required at the local level. Frequently, synthetic jet ejectors are utilized in conjunction with a conventional fan based system. In such hybrid systems, the fan based system provides a global flow of fluid through the device being cooled, and the synthetic jet ejectors provide localized cooling for hot spots and also augment the global flow of fluid through the device by perturbing boundary layers.

Various examples of synthetic jet ejectors are known to the art. Some examples include those disclosed in U.S. 20070141453 (Mahalingam et al.) entitled “Thermal Management of Batteries using Synthetic Jets”; U.S. 20070127210 (Mahalingam et al.), entitled “Thermal Management System for Distributed Heat Sources”; 20070119575 (Glezer et al.), entitled “Synthetic Jet Heat Pipe Thermal Management System”; 20070119573 (Mahalingam et al.), entitled “Synthetic Jet Ejector for the Thermal Management of PCI Cards”; 20070096118 (Mahalingam et al.), entitled “Synthetic Jet Cooling System for LED Module”; 20070081027 (Beltran et al.), entitled “Acoustic Resonator for Synthetic Jet Generation for Thermal Management”; and 20070023169 (Mahalingam et al.), entitled “Synthetic Jet Ejector for Augmentation of Pumped Liquid Loop Cooling and Enhancement of Pool and Flow Boiling”.

### BRIEF DESCRIPTION OF THE DRAWINGS

FIG. 1 is a perspective view of an LED module made in accordance with the teachings herein.

FIG. 2 is an exploded view of the LED module of FIG. 1.

FIG. 3 is an exploded view of the LED module of FIG. 1.

FIG. 4 is a cross-section taken along LINE 4-4 of FIG. 1.

FIG. 5 is a perspective view of the LED module of FIG. 1.

FIG. 6 is a perspective view showing the interior of the upper exterior housing element of the LED module of FIG. 1.

FIG. 7 is a perspective view showing the top of the upper actuator housing element of the LED module of FIG. 1.

FIG. 8 is a perspective view showing the interior of the upper actuator housing element of the LED module of FIG. 1.

FIG. 9 is a perspective view showing the first and second actuators of the LED module of FIG. 1.

FIG. 10 is a perspective view showing the first and second actuators of the LED module of FIG. 1.

FIG. 11 is a perspective view showing the lower actuator housing element of the LED module of FIG. 1.

FIG. 12 is a perspective view showing the lower actuator housing element of the LED module of FIG. 1.

FIG. 13 is a perspective view showing the interior of the lower exterior housing element of the LED module of FIG. 1.

FIG. 14 is a perspective view showing the exterior of the lower exterior housing element of the LED module of FIG. 1.

FIG. 15 is a perspective view showing the interior of the heat sink of the LED module of FIG. 1.

FIG. 16 is a perspective view showing the bottom of the heat sink of the LED module of FIG. 1.

FIG. 17 is an illustration showing a synthetic jet actuator coupled with a vibration dampening means.

FIG. 18 is an illustration showing a synthetic jet actuator coupled with a vibration dampening means.

FIG. 19 is an illustration showing a synthetic jet actuator coupled with a vibration dampening means.

FIG. 20 is an illustration showing a synthetic jet actuator coupled with a vibration dampening means.

FIG. 21 is an illustration showing a synthetic jet actuator coupled with a vibration dampening means.

FIG. 22 is an illustration showing a synthetic jet actuator coupled with a vibration dampening means.

FIG. 23 is a cross-sectional view of a variation of the embodiment depicted in FIG. 22.

FIG. 24 is an illustration showing a synthetic jet actuator coupled with a vibration dampening means.

FIG. 25 is a cross-sectional view of a variation of the embodiment depicted in FIG. 22.

FIG. 26 is a cross-sectional view of an LED module which utilizes a synthetic jet ejector in combination with a vibration dampening means.

FIG. 27 is an exploded view of the device of FIG. 26.

FIG. 28 is an exploded view of an LED module which utilizes a synthetic jet ejector in combination with a vibration dampening means.

### SUMMARY OF THE DISCLOSURE

In one aspect, a synthetic jet ejector is provided which comprises (a) an LED, (b) a heat sink, (c) a first synthetic jet actuator equipped with a first diaphragm which is adapted to vibrate such that it undergoes displacements along a first axis, and (d) a second synthetic jet actuator equipped with a second diaphragm which is adapted to vibrate such that it undergoes displacements in an opposite direction along said first axis from said first diaphragm.

In another aspect, a device is provided which comprises (a) a synthetic jet actuator equipped with a first actuator and a first diaphragm; and (b) a vibration dampening device adapted to vibrate out of phase with the first diaphragm.

In a further aspect, a device is provided which comprises (a) an LED; (b) a heat sink; (c) a first synthetic jet actuator equipped with a first diaphragm, said first diaphragm being adapted to vibrate such that it undergoes displacements along a first axis; and (d) a vibration dampening device equipped with a second diaphragm, said second diaphragm being adapted to vibrate such that it undergoes displacements in an opposite direction along said first axis from said first diaphragm.

In still another aspect, a device is provided which comprises (a) an LED; (b) a heat sink; (c) a first synthetic jet actuator equipped with a first diaphragm, said first diaphragm being adapted to vibrate such that it undergoes displacements along a first axis; and (d) a vibration dampening device equipped with a second diaphragm, said second diaphragm being adapted to vibrate so as to dampen the vibrations produced by the first diaphragm.

In a further aspect, a method is provided for reducing vibrations in a synthetic jet ejector equipped with a first actuator and a first diaphragm. In accordance with the method, a vibration dampening device is provided, and is operated out of phase with the first diaphragm.

### DETAILED DESCRIPTION

While many advances have been made in the implementation of synthetic jet technology, there is a need for further improvements in the art, especially in particular end use applications. For example, in some applications, such as the thermal management of LEDs in lighting applications, it has been found that synthetic jet ejectors may give rise to an unacceptably large vibrational amplitude. Such vibrations are undesirable in that they can harm the host device, and also tend to give rise to acoustic emissions.

It has now been found that this problem may be reduced or eliminated through the effective use of momentum cancellation. In some embodiments, this may be accomplished, for example, through the provision of a synthetic jet ejector having at least first and second synthetic jet actuators which are positioned such that their moving portions move along a common axis but in opposite directions. The resulting equal, but opposite, motion may be utilized to cancel some or all of the net vibration from the synthetic jet ejector. In other embodiments, a similar end may be achieved through the effective use of a vibration dampening device in place of the second synthetic jet actuator. The vibration dampening device may be equipped with a second diaphragm which is adapted to vibrate such that it undergoes displacements in an opposite direction along said first axis from said first diaphragm.

The use of multiple actuators in some of the embodiments described herein gives rise to a variety of unique designs for thermal management systems. For example, embodiments may be made in accordance with the teachings herein which utilize housings having a configuration of flow passages designed therein equipped to efficiently direct airflow from both sides of each actuator. The resulting pattern of synthetic jets is well suited for use in conjunction with a variety of heat sinks of various geometries including, for example, cylindrical heat sinks having both exterior and interior surfaces for heat transfer. Such embodiments are particularly useful for applications such as discrete, high-power LEDs. Embodiments may also be made in accordance with the teachings herein which utilize a relatively small number of moldable parts. Such embodiments are particularly conducive to high volume production.

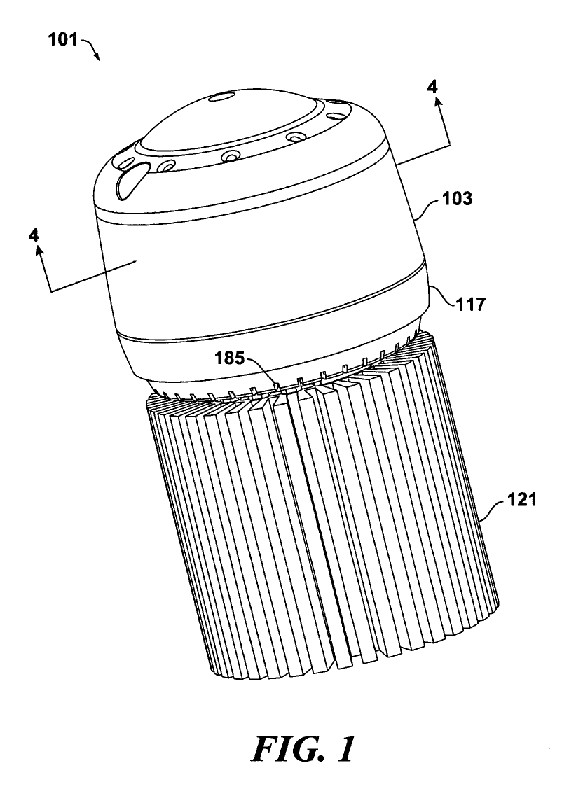

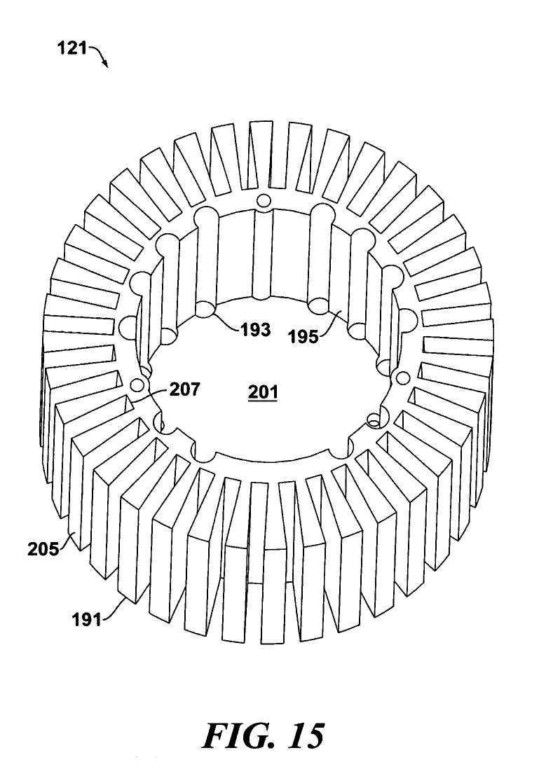

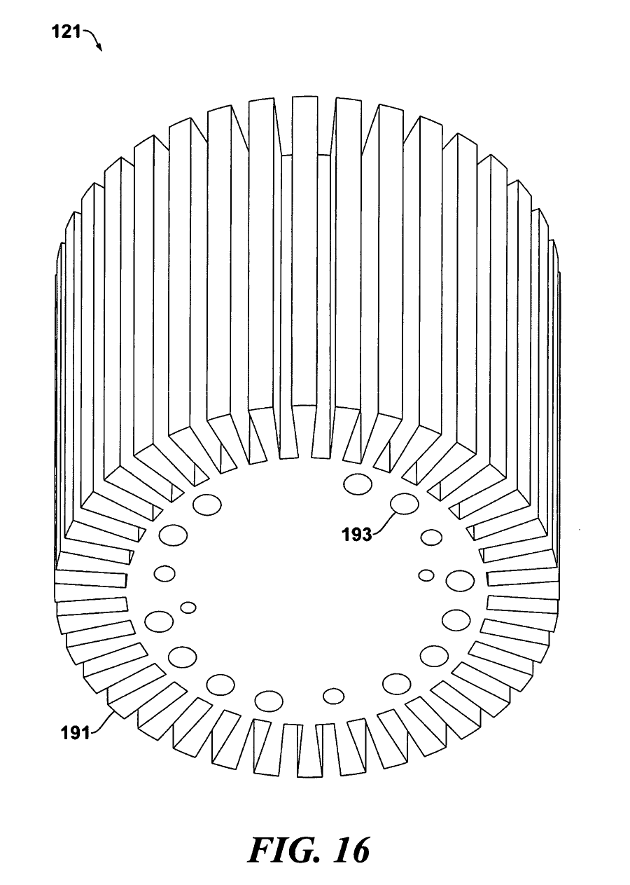

FIGS. 1-16 depict a first particular, non-limiting embodiment of an LED module made in accordance with the teachings herein. With reference to FIG. 1, the LED module 101 comprises an upper exterior housing element 103 which is coupled to a lower exterior housing element 117. The lower exterior housing element is, in turn, coupled to a heat sink 121 and is provided with a plurality of apertures 185, each of which is adapted to dissipate heat by directing a synthetic jet into one of a plurality of channels 207 (see FIG. 15) defined by opposing fins 205 of the heat sink 121.

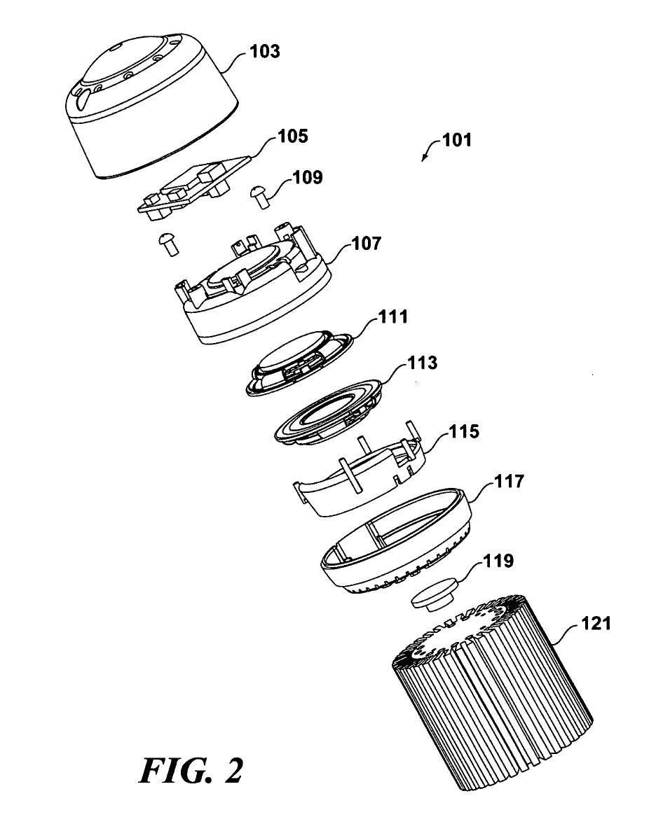

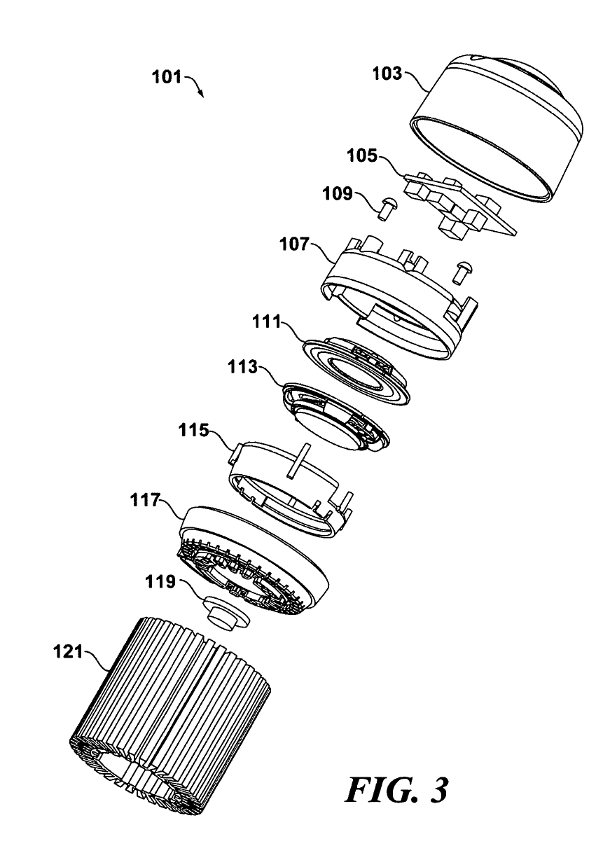

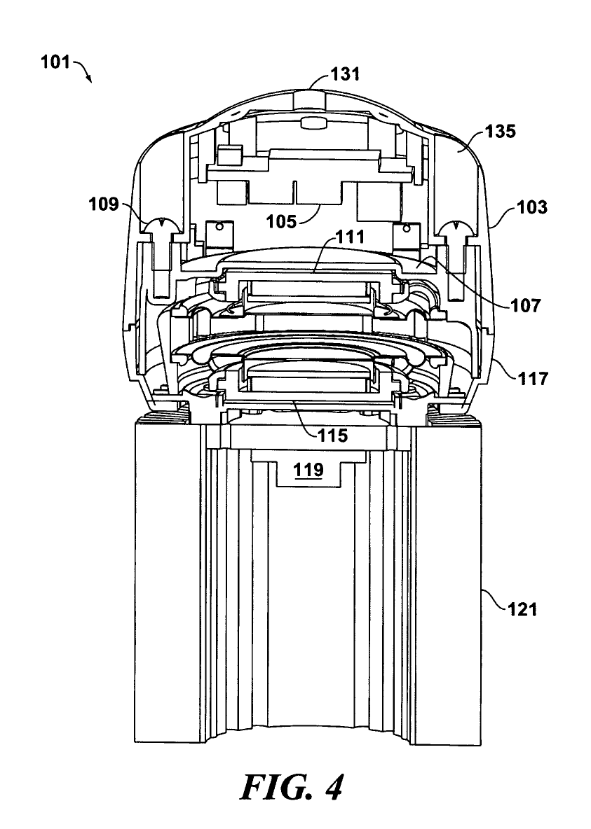

The interior details of the LED module 101 may be appreciated with respect to the exploded views thereof shown in FIG. 2-3, and the cross-sectional view shown in FIG. 4. As seen therein, the LED module 101 is controlled by logic embedded in a printed circuit board (PCB) 105, which is disposed in the space between the upper exterior housing element 103 and the upper actuator housing element 107. A plurality of fasteners 109 are also provided to secure the upper exterior housing element 103 to the upper actuator housing element 107.

The LED module 101 is further equipped with first 111 and second 113 synthetic jet actuators, which are oriented in an opposing relationship within upper actuator housing element 107 and lower actuator housing element 115. The assembly consisting of the upper 107 and lower 115 housing elements and the first 111 and second 113 actuators is, in turn, housed within upper 103 and lower 117 exterior housing elements. The lower exterior housing element 117 is secured to a heat sink 121 which contains an interior surface 201 (see FIG. 15) upon which the LED assembly 119 is seated (see FIG. 4).

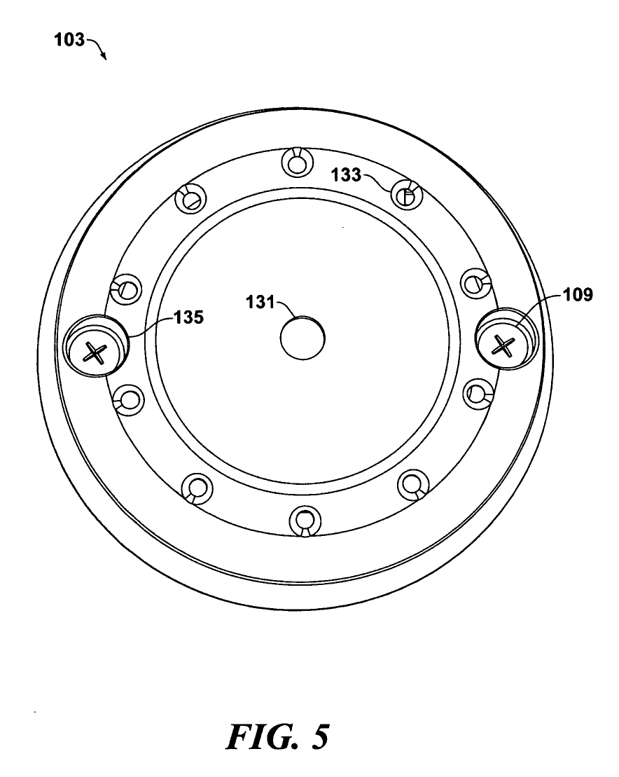

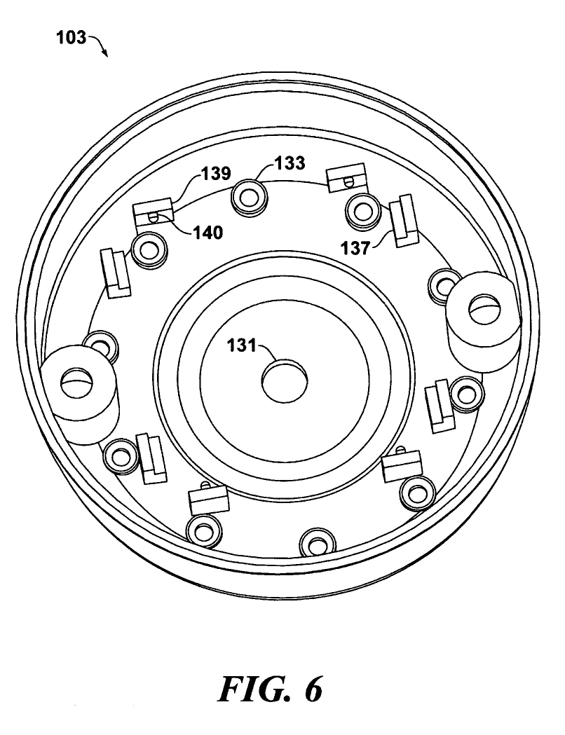

The details of the upper exterior housing element 103 may be appreciated with respect to FIGS. 5 and 6. As seen in FIG. 5, the upper exterior housing element 103 is equipped with a pair of apertures 135 through which corresponding fasteners 109 may be extended for the purpose of securing the upper exterior housing element 103 to the upper actuator housing element 107 as seen in FIG. 4. The upper exterior housing element 103 is also equipped with first 131 and second 133 sets of apertures. The first set of apertures 131 may be utilized for input power wiring and for optional control wiring, while the second set of apertures 133 are adapted to permit a convection-induced flow of air through the upper exterior housing element 103, thereby providing thermal management of the PCB 105. In some embodiments, the LED module 101 may be adapted such that one or more synthetic jets are emitted from the synthetic jet actuators 111, 113 and impinge upon the PCB 105.

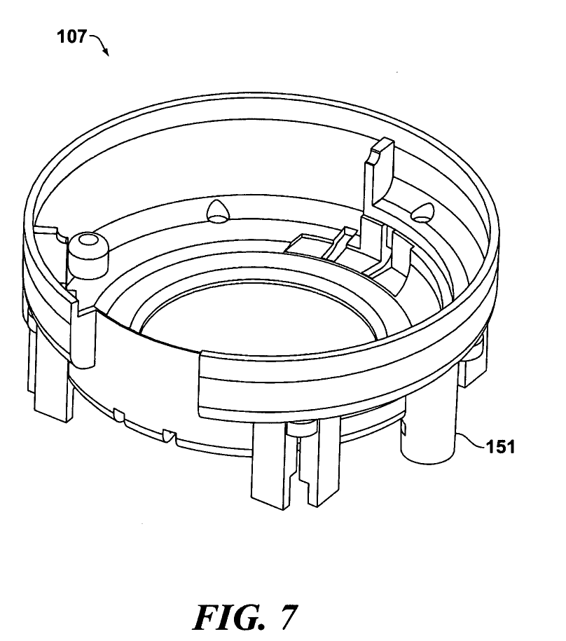

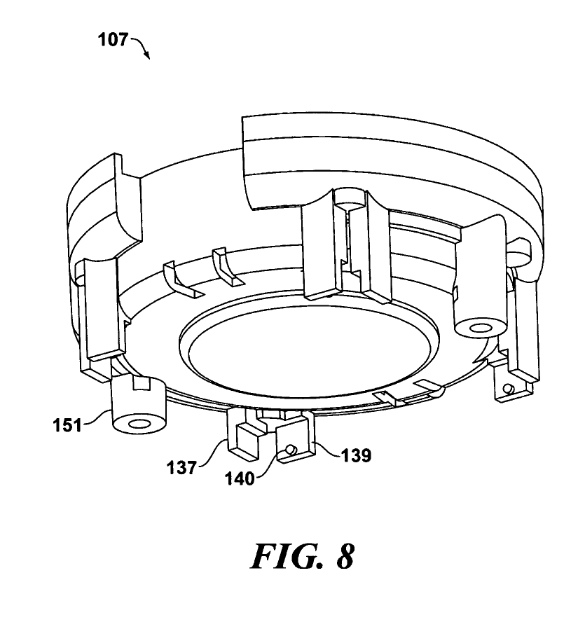

With reference to FIG. 6, the interior of the upper exterior housing element 103 is provided with a series of brackets 137, 139, the latter of which are equipped with a protrusion 140. These brackets 137, 139 and protrusions 140 allow the PCB 105 to be seated securely therein. With further reference to FIGS. 7-8, the upper actuator housing member 107 is also equipped with receptacles 151 for releasably receiving fasteners 109 (see FIGS. 2-4).

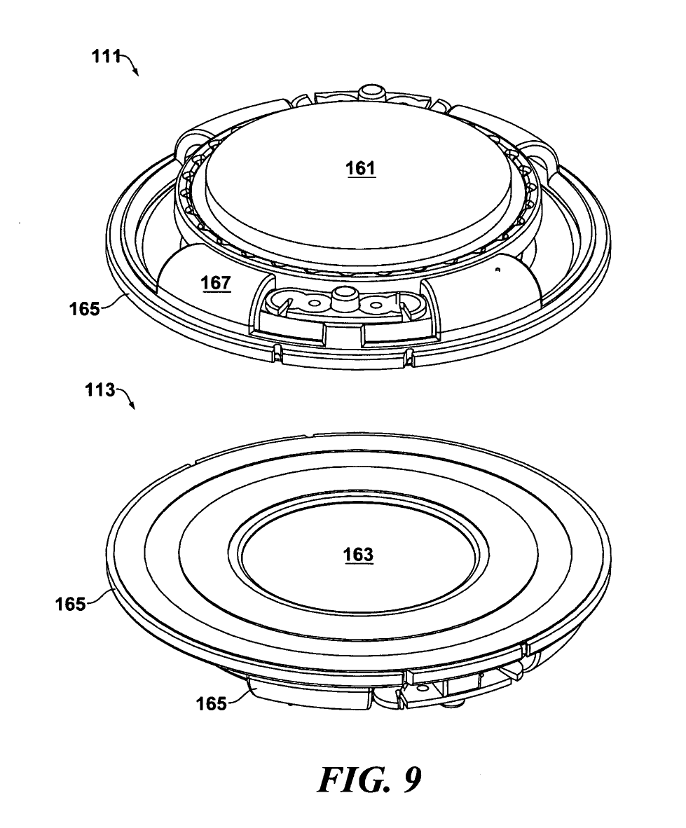

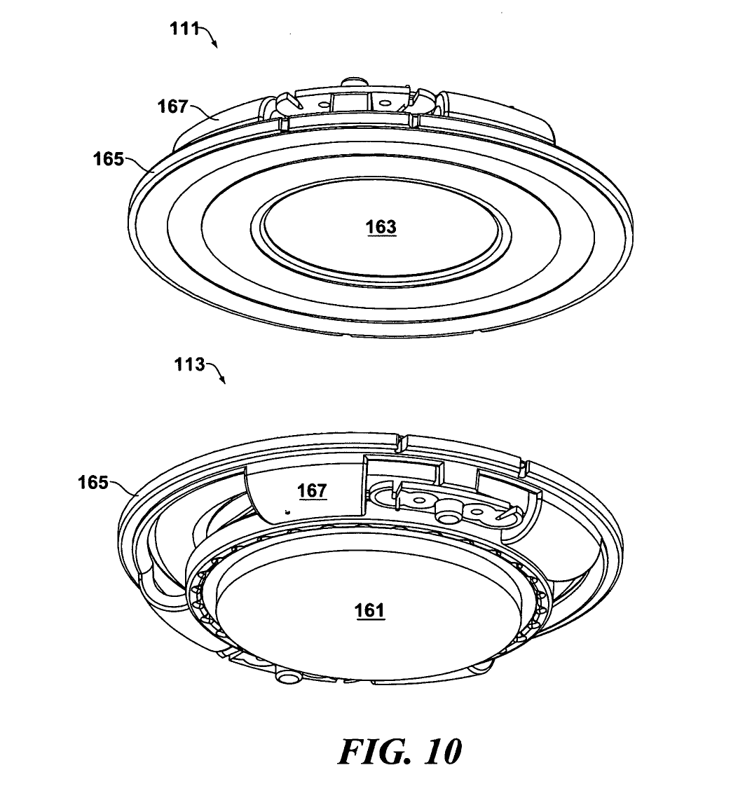

FIGS. 9-10 depict the actuators 111, 113 utilized in the LED module 101 to generate synthetic jets. As seen therein, these actuators 111, 113 are equipped on one side with a pot 161 which houses a permanent magnet 162, and are equipped on the opposing side with a diaphragm 163. The actuators 111, 113 include a basket 165 equipped with a series of tabs 167 defined therein. The tabs 167 of the first synthetic jet actuator 111 provide a keying function so that the first synthetic jet actuator 111 will be locked in place in the appropriate orientation.

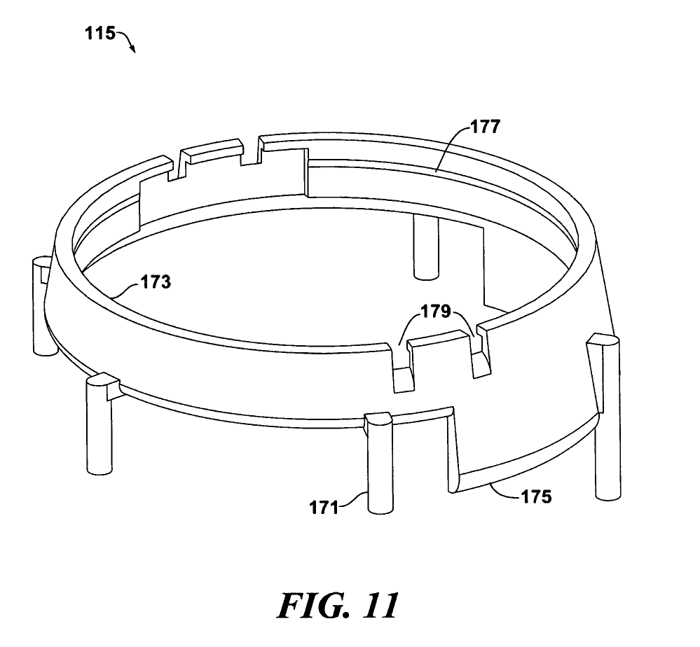

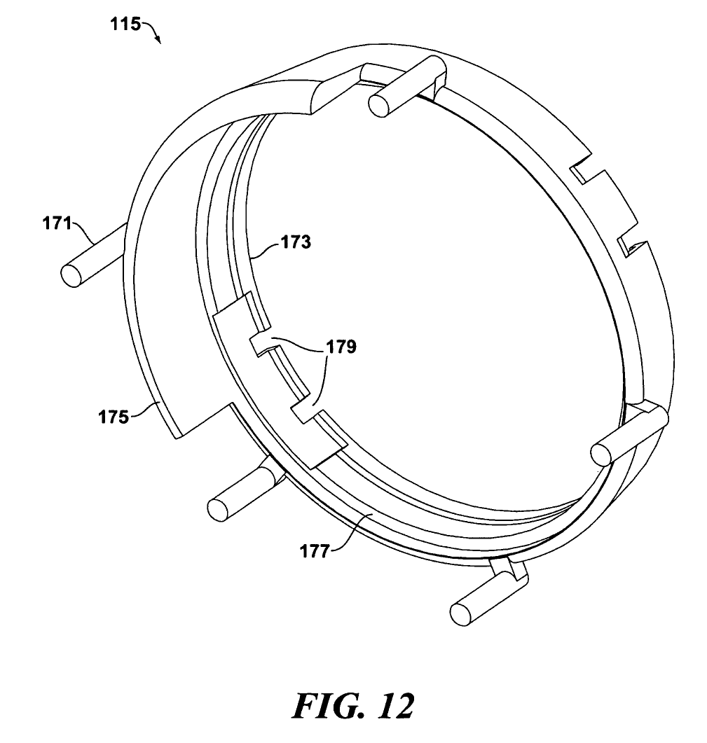

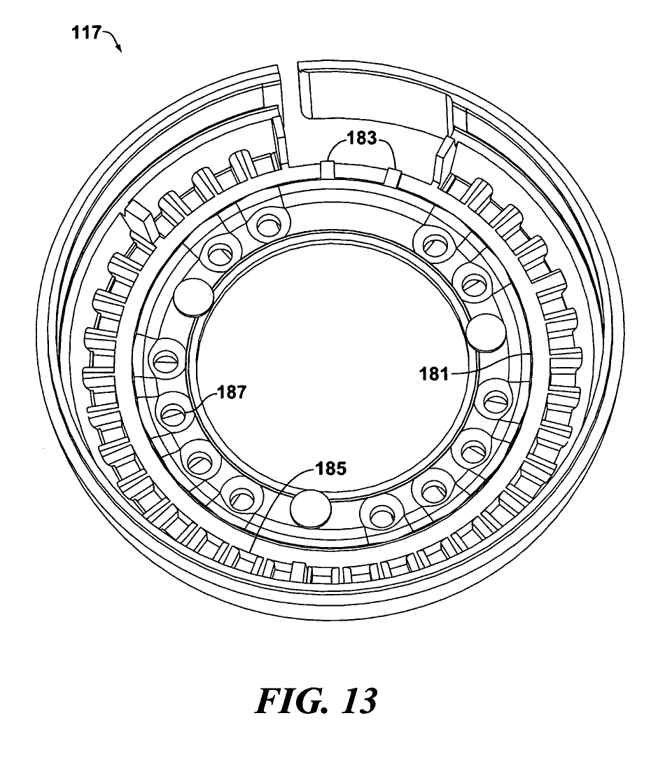

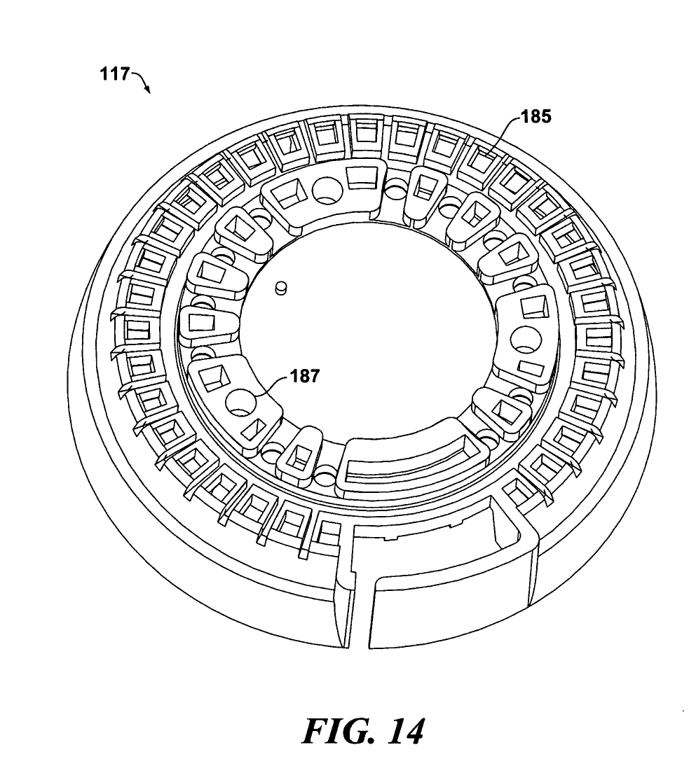

FIGS. 11-12 depict the lower actuator housing element 115 in greater detail. The lower actuator housing element 115 is equipped with a plurality of protrusions 171 which mate with opposing apertures 151 provided in the upper actuator housing member 107 (see FIGS. 7-8). The lower actuator housing member 107 has a lower annular edge 173 which sits within a complimentary shaped depression 181 formed in the lower exterior housing element 117 (see FIG. 13), as shown in FIG. 4. The lower actuator housing member 107 also has an upper annular edge 175 upon which the upper actuator 111 is seated flush with an annular lip 177 upon which the lower actuator 113 is seated. The lower actuator housing member 107 is further equipped with a set of opposing slots 179 which engage a set of complimentary shaped protrusions 183 on the lower exterior housing element 117 (see FIGS. 13-14) to provide a keying function for appropriate orientation of the lower actuator housing element 115.

Referring now to FIGS. 13-14, the lower exterior housing element 117 is equipped with a first set of apertures 185 which are adapted to direct a plurality of synthetic jets between adjacent fins 191 of heat sink 121. As seen from the cross-sectional view in FIG. 4, the first set of apertures 185 are in fluidic communication with both the first synthetic jet actuator 111 and the second synthetic jet actuator 113 by way of a channel defined by the interior surfaces of the lower actuator housing member 107, the lower exterior housing element 117, and the exterior surface of the lower actuator housing element 115. The lower exterior housing element 117 is further equipped with a second set of apertures 187 which are adapted to direct a plurality of synthetic jets along the longitudinal axes of a plurality of channels 193 defined in the interior wall 195 of the heat sink 121.

In the foregoing embodiment, vibration dampening is achieved through the provision of a synthetic jet ejector having at least first and second synthetic jet actuators which are positioned such that the moving portions of the actuators move along a common axis but in opposite directions. However, in other embodiments, as where it is impractical or undesirable to utilize multiple synthetic jet actuators, a similar effect may be achieved through the use of vibration dampening devices. Such devices are not synthetic jet actuators themselves, but serve to cancel or reduce the vibrations produced by one or more synthetic jet actuators. Preferably, vibration dampening devices achieve this end by providing a product of mass and velocity which is essentially equal in magnitude, but opposite in sign, to that of an actuator diaphragm whose vibrations are to be cancelled. The vibration dampening device is preferably driven at the same frequency, but opposite phase, as the diaphragm of the synthetic jet actuator to which a dampening effect is to be applied.

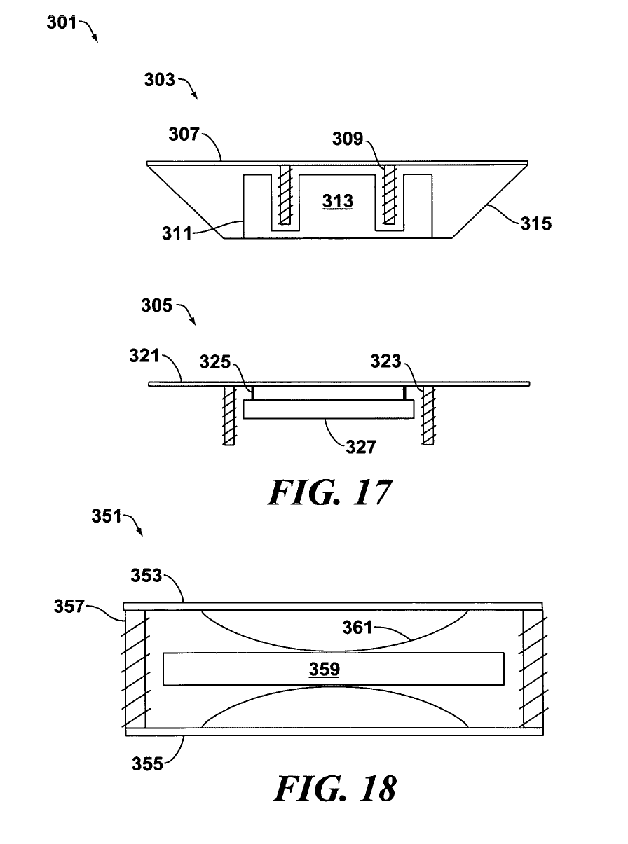

FIG. 17 shows one particular, non-limiting embodiment of a device 301 equipped with a synthetic jet actuator 303 and a vibration dampening device 305. The synthetic jet actuator 303 is similar to the types of synthetic jet actuators incorporated into other embodiments described herein, and comprises a diaphragm 307, an electrical coil 309, a frame 315, a permanent magnet 313 and a pot 311. The vibration dampening device 305 comprises a diaphragm 321 (which may comprise, for example, a flexible material, a leaf spring, or a spiral spring) from which a counterweight 327 is suspended within an electrical coil 323 by way of a suitable material 325. The counterweight includes a magnet, and may further include additional materials to add mass to it. Though the vibration dampening device 305 is depicted here as a separate device, it may be situated in close proximity to, or may be attached to, the synthetic jet actuator 303.

In operation, the vibration dampening device 305 is operated such that the counterweight moves in the opposite direction from the diaphragm to cancel out vibrations. Hence, the device 301 is operated in accordance with EQUATION 1:

m_{d}v_{d}=−m_{cw}v_{cw} (EQUATION 1)

wherein m_{d} is the mass of the diaphragm, v_{d} is the velocity of the diaphragm, m_{cw} is the mass of the counterweight, and v_{cw} is the velocity of the counterweight. Alternatively, this relationship may be described as

m_{d}k_{d}A_{d} cos ωt=−m_{cw}k_{cw}A_{cw} cos ωt (EQUATION 2)

where m_{d} is the mass of the diaphragm, k_{d} is the spring constant of the diaphragm, A_{d} is the amplitude of the diaphragm, m_{cw} is the mass of the counterweight, k_{cw} is the spring constant of the counterweight, A_{cw} is the amplitude of the counterweight, and t is time. Consequently, the total force (Fₜₒₜₐₗ) experienced by the device 301 is equal to zero, as shown by EQUATION 3:

F=d(mvₜₒₜₐₗ)/dt=0 (EQUATION 3)

FIG. 18 shows another particular, non-limiting embodiment of a vibration dampening device of the type suitable for use in conjunction with a synthetic jet actuator 303 of the type depicted in FIG. 17. The vibration dampening device 351 of FIG. 18 comprises first 353 and second 355 opposing diaphragms, an electrical coil 357, and a magnet 359 supported between opposing springs 361. This device operates in a similar manner to vibration dampening device 305, except that the opposing springs 361 provide greater control over the motion of the magnet 359 in certain applications.

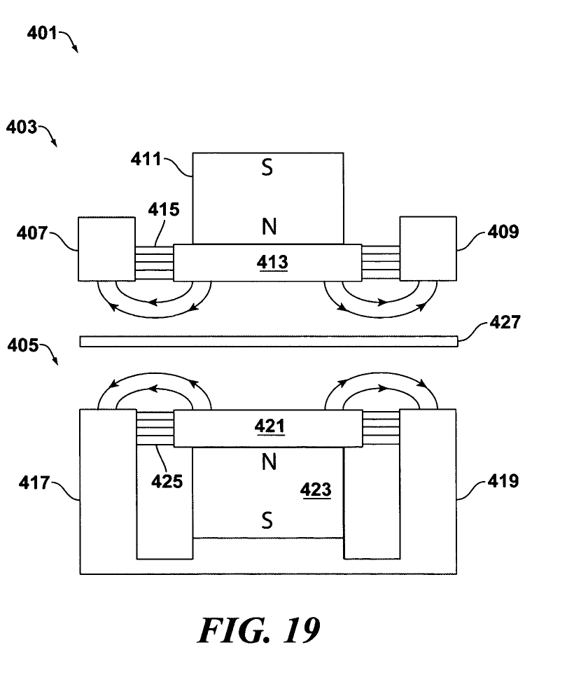

FIG. 19 illustrates a further particular, non-limiting embodiment of a device 401 equipped with a synthetic jet actuator 403 and a vibration dampening device 405 in accordance with the teachings herein. This device 401 operates in a manner somewhat similar to that of the device of FIG. 17. However, in the device 401 of FIG. 19, magnetic interactions between the synthetic jet actuator 403 and the vibration dampening device 405 are minimized through the provision of a thin layer 427 of a high magnetic permeability (μ) material. Consequently, the effect of the magnetic field of the vibration dampening device 405 on the synthetic jet actuator 403 may be reduced or eliminated.

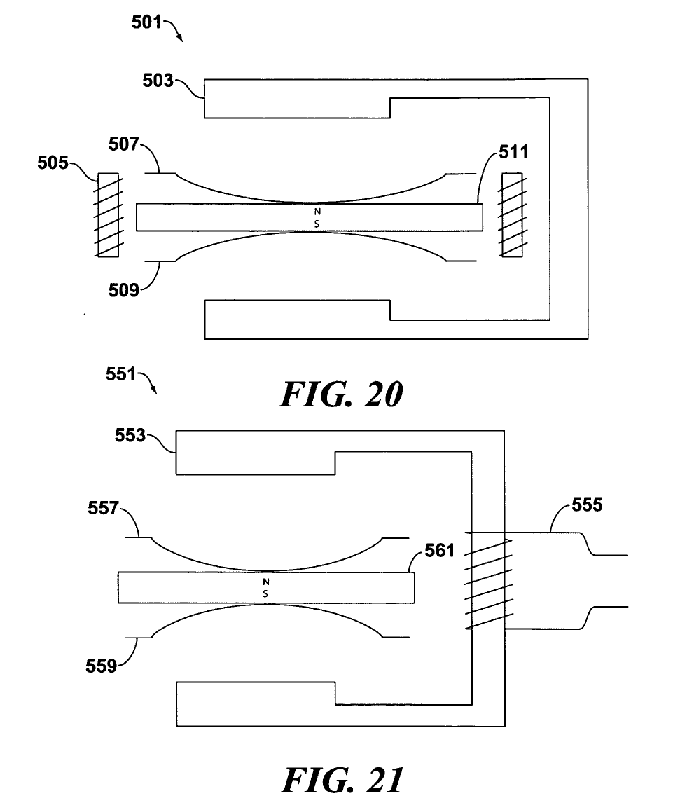

FIG. 20 illustrates a further particular, non-limiting embodiment of a vibration dampening device in accordance with the teachings herein. In this embodiment, the vibration dampening device 501, which is otherwise similar to the device depicted in FIG. 18, is equipped with a high magnetic permeability (μ) gap spacer 503. The electrical coil 505, the first 507 and second 509 springs, and the magnet 511 of the vibration dampening device 501 are placed inside of the high magnetic permeability gap spacer 503. The magnetic field of the magnet 511 is thus essentially confined to the area within the gap spacer 503, making this device suitable for applications in which magnetic interaction between the vibration dampening device and a synthetic jet actuator or other device component is undesirable.

FIG. 21 illustrates a further particular, non-limiting embodiment of a vibration dampening device in accordance with the teachings herein. The device 551 depicted therein is similar in most respects to the embodiment depicted in FIG. 20. Thus, the vibration dampening device 551 is equipped with a low magnetic permeability gap spacer 553, and the first 557 and second 559 springs and the magnet 561 of the vibration dampening device 551 are placed inside of the low magnetic permeability gap spacer 553. In this embodiment, however, a magnetic coil 555 is provided on the gap spacer 553 to control magnetic field flux.

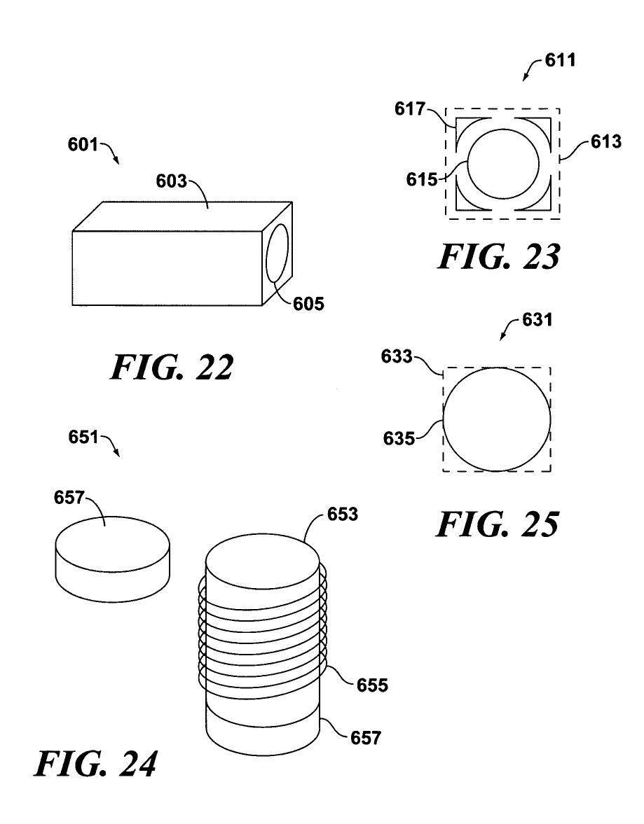

FIGS. 22-25 illustrate some further particular, non-limiting embodiments of vibration dampening devices in accordance with the teachings herein. With reference to FIG. 24, the device 651 depicted therein comprises a hollow tube 653 having a coil 655 disposed about the surface thereof. One or more metal weights 657 are provided within the tube 653 (the weight is shown removed from the tube for clarity of illustration). The metal weights 657 can move up and down inside of the tube 653 as the current is varied to provide vibration dampening. In some variations of this embodiment, a spring (not shown) may be provided to restore/return the metal weights 657 more efficiently. It will be appreciated, of course, that weights and tubes of various geometries can be used in this type of embodiment, including weights and tubes which are circular, elliptical, rectangular, square, polygonal, or irregular in cross-section. Moreover, the interior and exterior geometries of the tube may be the same or different, and may be selected from any of the foregoing shapes. Preferably, however, the weight 657 is complimentary in shape to the interior shape of the tube 653.

With reference to FIG. 22, the embodiment of the vibration dampening device 601 depicted therein is similar to that of FIG. 24 except that, in the device 601 of FIG. 22, the housing 603 has an exterior which is rectangular in cross-section and an interior 605 which is circular in cross-section. In the embodiment 611 depicted in the cross-section of FIG. 23, the metal weight 617 comprises four distinct portions disposed between the housing 613 and a central cylinder 615, while in the device 631 shown in FIG. 25, the metal weight 635 is housed within a rectangular housing 633. Any of these embodiments may be equipped with a coil as shown in the device of FIG. 24, and the weights within these devices may be equipped with one or more springs to provide more efficient return of the weights to a given position.

It will be appreciated from the foregoing embodiments that, in devices made in accordance with the teachings herein, the areas around an actuator (such as the corners in an actuator having a generally rectangular shape) may be utilized to house weights for vibration dampening purposes. This approach is particularly desirable for space constrained designs such as those featuring a circular (in cross-section) actuator disposed within a square housing since, in such designs, the area bounded by the two shapes is essentially empty space. The geometry of the weights disposed in such spaces may be selected based on the geometry of the space. Thus, for example, the weights may be polygonal (including triangular, square, rectangular, or hexagonal) or round.

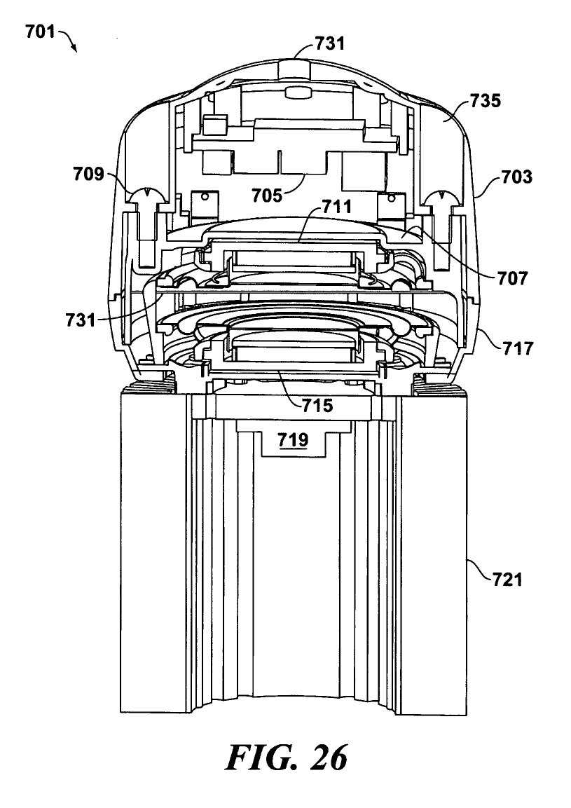

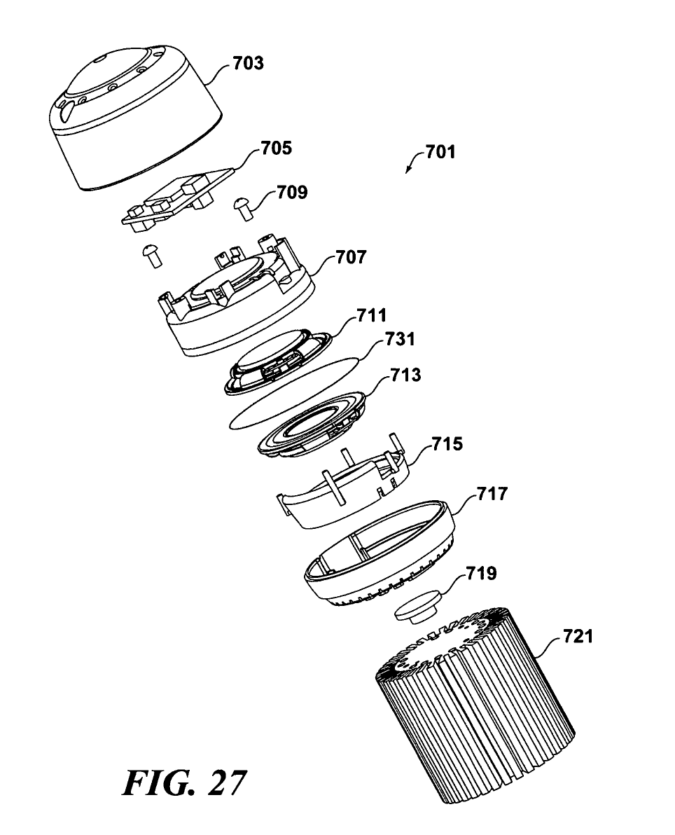

Various embodiments are also possible in accordance with the teachings herein in which one or more synthetic jet actuators may be modified to serve as a vibration dampening device, and thereby provide vibration dampening or cancellation for another synthetic jet ejector. FIGS. 26-28 illustrate embodiments of such a device.

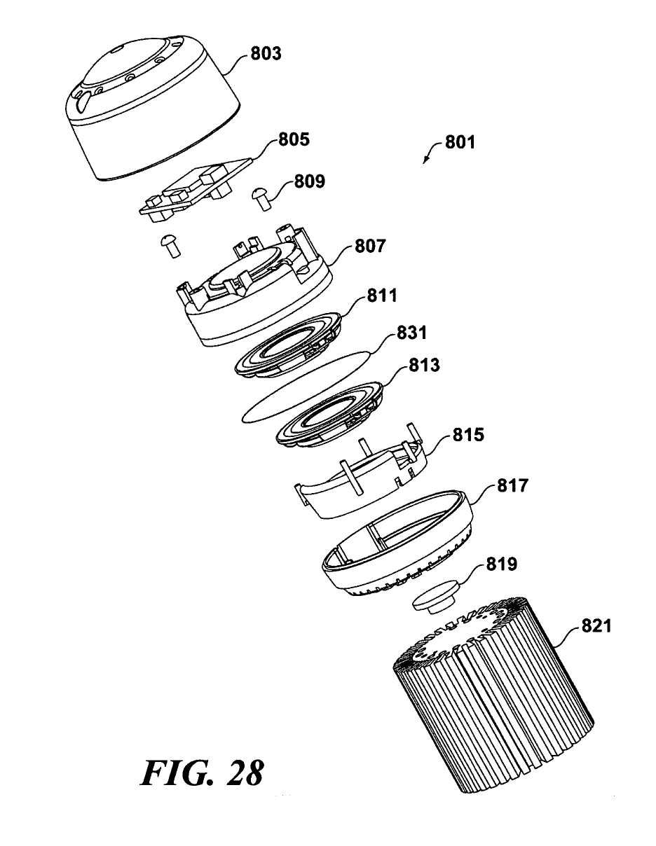

The LED module 701 of FIGS. 26-27 is similar to the LED module 101 of FIGS. 1-16 (note that like elements have similar reference numerals). However, unlike the LED module 101, LED module 701 is equipped with a septum 731 which fluidically isolates vibration dampening element 711 from synthetic jet actuator 713 (and from the nozzles of the device). However, because vibration dampening element 711 is essentially identical to synthetic jet actuator 713, vibration dampening element 711 may be run out-of-phase with synthetic jet actuator 713 such that vibration dampening is achieved through cancellation.

FIG. 27 illustrates a further embodiment of an LED module 801 which utilizes vibration dampening. The LED module 801 of FIG. 27 is similar in most respects to that of the LED module 701 of FIGS. 25-26. However, in this embodiment, vibration dampening device 811 faces away from synthetic jet actuator 813. An optional septum 831 is provided to fluidically isolate vibration dampening device 811 from synthetic jet actuator 813, though in some cases the upper actuator housing element 807 and/or the vibration dampening device 811 itself may be adapted to provide a suitable fluidic seal. For example, the vibration dampening device 811 may be equipped with a sealed surface and may have a circumference which mates snugly with upper actuator housing element 807 so that it is fluidically isolated from synthetic jet actuator 813.

Various means may be utilized to control a pair of synthetic jet actuators (an actuator/actuator pair) or a synthetic jet actuator paired with a vibration dampening device (an actuator/compensator pair) to achieve a minimal or net zero momentum in accordance with the teachings herein. In one preferred embodiment, one or more accelerometers are coupled to, or associated with, the actuator/actuator or actuator/compensator pair. The signal from the accelerometer is then fed into the electronic control circuitry of the associated device, where it may be utilized by the control circuitry to adjust phase and/or amplitude ratios between the actuators, or between the actuator and the vibration dampener, to minimize vibrations. It will be appreciated that the use of an accelerometer is especially useful in embodiments in which the actuator/actuator or actuator/compensator pair is asymmetrical, or in which the components of the pair differ in mass.

In embodiments which utilize an accelerometer, the accelerometer may be disposed in various places within or on the device. Preferably, the accelerometer is disposed on a diaphragm or on a counterweight. More generally, however, the accelerometer may be placed on or within another moving component of an actuator of a synthetic jet ejector and/or a vibration dampening device.

The above description of the present invention is illustrative, and is not intended to be limiting. It will thus be appreciated that various additions, substitutions and modifications may be made to the above described embodiments without departing from the scope of the present invention. Accordingly, the scope of the present invention should be construed in reference to the appended claims.

What is claimed is:

1. A device, comprising:
a synthetic jet actuator equipped with a first actuator and a first diaphragm; and
a vibration dampening device adapted to vibrate out of phase with the first diaphragm.

2. The device of claim 1, wherein said first diaphragm is adapted to vibrate such that it undergoes displacements along a first axis.

3. The device of claim 2, wherein the first axis is perpendicular to said first diaphragm.

4. The device of claim 2, wherein said second diaphragm is adapted to vibrate such that it undergoes displacements in an opposite direction along said first axis from said first diaphragm.

5. The device of claim 1, wherein said vibration dampening device comprises a weight which vibrates out of phase with the first diaphragm.

6. The device of claim 5, wherein the first diaphragm and the weight vibrate essentially in accordance with the relationship
m_{d}v_{d}=−m_{w}v_{w}
wherein m_{d} is the mass of the diaphragm, v_{d} is the velocity of the diaphragm, m_{w} is the mass of the weight, and v_{w} is the velocity of the weight.

7. The device of claim 1, wherein the vibration dampening device is equipped with a second diaphragm.

8. The device of claim 1, wherein said vibration dampening device comprises a second actuator.

9. The device of claim 1, further comprising a heat sink.

10. The device of claim 9, further comprising an LED.

11. The device of claim 9, wherein said synthetic jet actuator is adapted to direct a first plurality of synthetic jets across a first surface of said heat sink.

12. The device of claim 9, wherein said heat sink has an interior surface and an exterior surface.

13. The device of claim 12, wherein said heat sink is essentially annular in shape and has a plurality of fins disposed on said exterior surface.

14. The device of claim 1, wherein said device comprises a housing having a first passageway defined therein which is in open communication with said synthetic jet actuator and said exterior surface of said heat sink.

15. The device of claim 1, wherein said synthetic jet ejector is fluidically isolated from said vibration dampening device.

16. The device of claim 14, wherein said housing consists of no more than four parts which are molded from a thermoplastic material.

17. The device of claim 14, wherein said first passageway is in open communication with a first plurality of apertures.

18. The device of claim 17, wherein said housing has a second passageway therein which is in open communication with a second plurality of apertures.

19. The device of claim 18, wherein said first plurality of apertures emits a first plurality of synthetic jets, and wherein said second plurality of apertures emits a second plurality of synthetic jets.

20. The device of claim 1, wherein said vibration dampening device further comprises a magnet and an electrical coil.

21. The device of claim 19, wherein said magnet is disposed between first and second opposing springs.

22. The device of claim 1, further comprising an accelerometer.

23. The device of claim 1, further comprising a layer of a high magnetic permeability material disposed between said synthetic jet actuator and said vibration dampening device.

24. The device of claim 8, wherein said second actuator is equipped with a magnet, and wherein said magnetic is disposed within a high magnetic permeability gap spacer.

25. The device of claim 24, wherein said second actuator is further equipped with an electrical coil.

26. A method for reducing vibrations in a synthetic jet ejector equipped with a first actuator and a first diaphragm, the method comprising:
providing a vibration dampening device; and
operating the vibration dampening device out of phase with the first diaphragm.

27. The method of claim 26, wherein the vibration dampening device is not a synthetic jet actuator.

28. The method of claim 26, wherein the vibration dampening device comprises
